(19) United States
(12) Patent Application Publication
(10) Pub. No.: US 2014/0153209 A1
(43) Pub. Date: Jun. 5, 2014

(54) COIL COMPONENT AND DISPLAY DEVICE INCLUDING THE SAME

(71) Applicant: SAMSUNG ELECTRO-MECHANICS CO., LTD., Suwon (KR)

(72) Inventors: Ki Hung NAM, Suwon (KR); Duck Jin AN, Suwon (KR); Soon Young KWON, Suwon (KR)

(73) Assignee: SAMSUNG ELECTRO-MECHANICS CO., LTD., Suwon (KR)

(21) Appl. No.: 13/770,775

(22) Filed: Feb. 19, 2013

(30) Foreign Application Priority Data
Nov. 30, 2012 (KR) 10-2012-0138430

(51) Int. Cl. H01F 17/00; H05K 5/00

(52) U.S. Cl. CPC H01F 17/0006; H05K 5/0017
USPC 361/782; 336/200

(57) ABSTRACT

There are provided a coil component capable of decreasing leakage inductance and a display device including the same. The coil component includes a cylindrical body part having a plurality of coils wound and stacked on an outer peripheral surface thereof; and one or more spacing parts formed on the outer peripheral surface of the body part to uniformly distribute the coils directly wound on the body part.

### CROSS-REFERENCE TO RELATED APPLICATIONS

This application claims the priority of Korean Patent Application No. 10-2012-0138430 filed on Nov. 30, 2012, in the Korean Intellectual Property Office, the disclosure of which is incorporated herein by reference.

### BACKGROUND OF THE INVENTION

1. Field of the Invention

The present invention relates to a coil component, and more particularly, a coil component capable of decreasing leakage inductance and a display device including the same.

2. Description of the Related Art

Various kinds of power supply units are required in a range of electronic devices including televisions (TVs), monitors, personal computers (PCs), office automation (OA) devices, and the like. Therefore, these electronic devices generally include a power supply unit converting alternating current (AC) power supplied from an external power source into power appropriate to operate respective electronic appliances.

Among power supply units, a power supply unit using a switching mode (for example, a switching mode power supply (SMPS)) has recently been in general use. Such an SMPS includes a switching transformer as a basic element thereof.

Generally, as compared to a general transformer, a switching transformer includes a core and a bobbin having a significantly reduced size, and stably supplies low voltage and low current direct current (DC) power to the electronic appliance. Therefore, the switching transformer has been widely used in electronic appliances that have tended to be miniaturized.

This switching transformer needs to be designed to have a small degree of leakage inductance in order to increase energy conversion efficiency. However, in accordance with miniaturization of the switching transformer, it may not be easy to design a switching transformer having a small degree of leakage inductance.

### RELATED ART DOCUMENT

(Patent Document 1) Korean Patent Laid-Open Publication No. 2006-0067630

### SUMMARY OF THE INVENTION

An aspect of the present invention provides a coil component capable of decreasing leakage inductance, and a display device including the same.

According to an aspect of the present invention, there is provided a coil component, including: a cylindrical body part having a plurality of coils wound and stacked on an outer peripheral surface thereof; and one or more spacing parts formed on the outer peripheral surface of the body part to uniformly distribute the coils directly wound on the body part.

The spacing parts may be protruded from the body part while having a height equal to or less than a diameter of the coil.

The spacing parts may be formed to have a partition wall shape and include one or more skip grooves.

The spacing parts may be formed as a plurality of protrusions.

A space between two adjacent spacing parts may be formed to have a width corresponding to the diameter of the coil.

The coils may be stacked and wound on ends of the spacing parts.

The spacing parts may be formed as grooves in the body part, the groove having a depth equal to or shallower than a diameter of the coil.

The coils directly wound on the body part may form a continuous outer peripheral surface, evenly with the spacing parts.

According to another aspect of the present invention, there is provided a coil component, including: a cylindrical body part having uneven portions formed on an outer peripheral surface thereof; and a plurality of coils stacked and wound on the uneven outer peripheral surface of the body part.

According to another aspect of the present invention, there is provided a display device, including: a power supply having at least one coil component as described above mounted on a substrate; and a display panel receiving power from the switching mode power supply.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view schematically showing a coil component according to an embodiment of the present invention;

FIG. 2 is an exploded perspective view of FIG. 1;

FIG. 3 is a cross-sectional view taken along line A-A′ of FIG. 1;

FIG. 4 is a partially enlarged cross-sectional view of FIG. 3;

FIG. 5 is a side view of a bobbin shown in FIG. 2;

FIGS. 6A and 6B are cross-sectional views schematically showing a coil component according to the related art;

FIGS. 7 through 9 are side views schematically showing coil components according to other embodiments of the present invention; and

FIG. 10 is an exploded perspective view schematically showing a display device according to an embodiment of the present invention.

### DETAILED DESCRIPTION OF THE EMBODIMENTS

Hereinafter, embodiments of the present invention will be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of components may be exaggerated for clarity, and the same reference numerals will be used throughout to designate the same or like components.

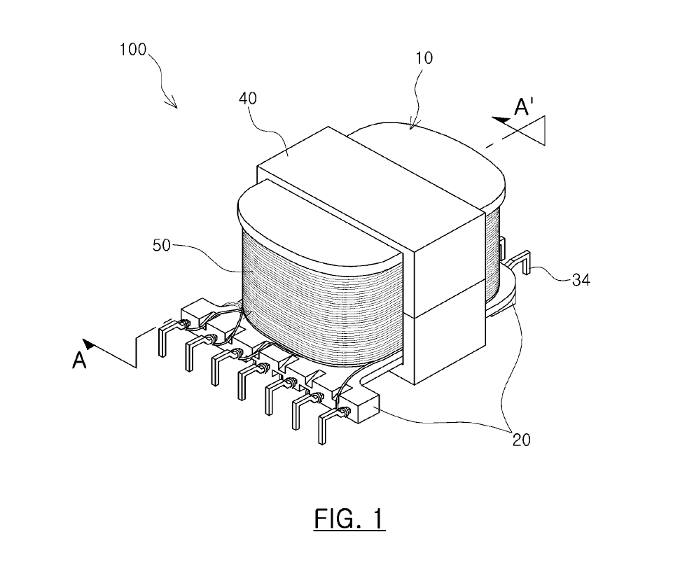

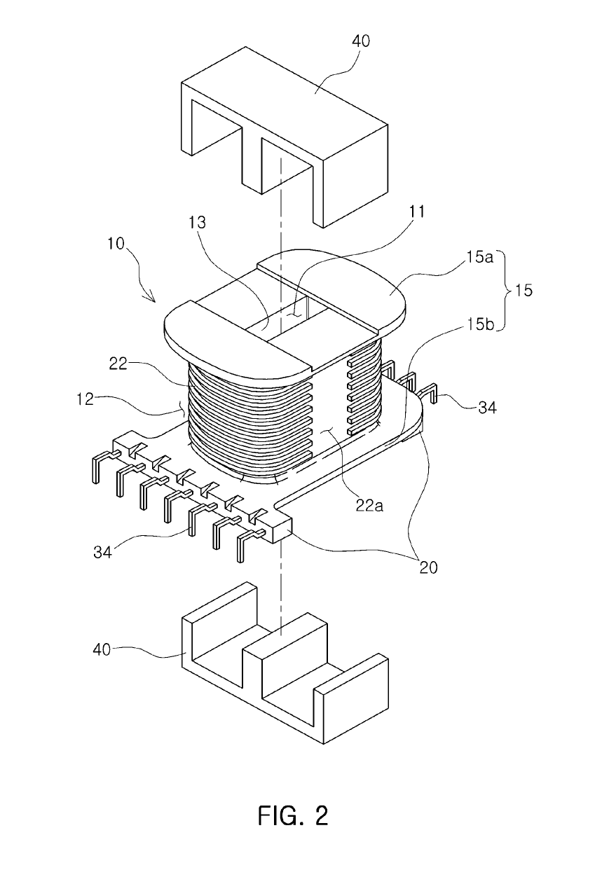

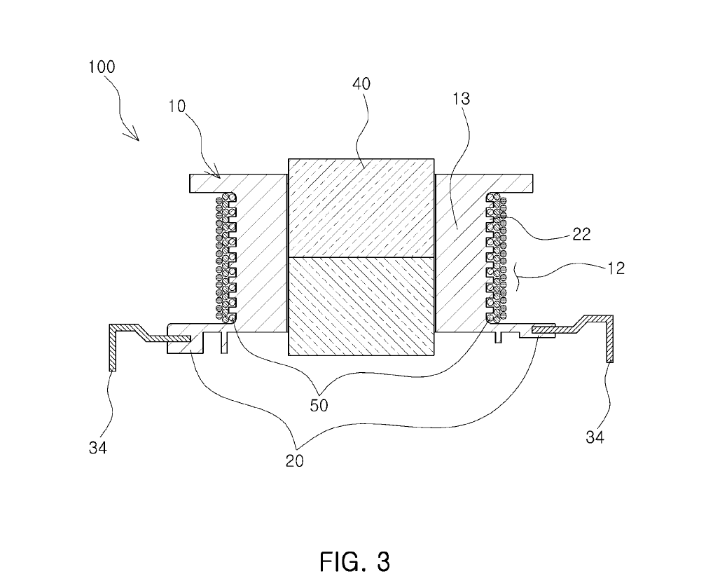

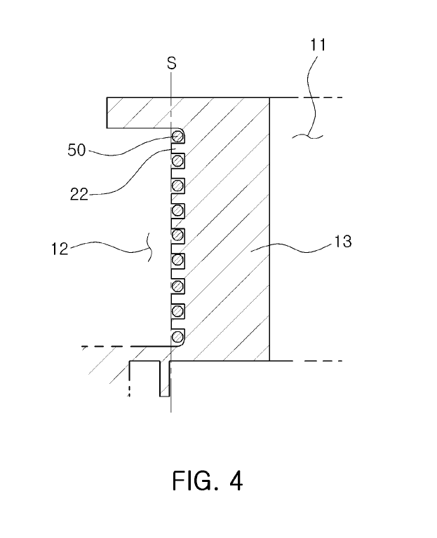

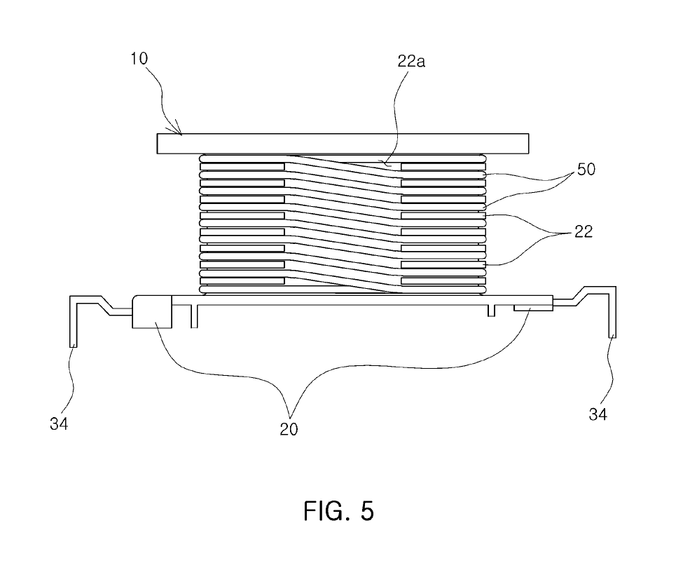

FIG. 1 is a perspective view schematically showing a coil component according to an embodiment of the present invention, FIG. 2 is an exploded perspective view of FIG. 1, and FIG. 3 is a cross-sectional view taken along line A-A′ of FIG. 1. In addition, FIG. 4 is a partially enlarged cross-sectional view of FIG. 3, and FIG. 5 is a side view of a bobbin shown in FIG. 2. Here, FIGS. 4 and 5 show a state in which only an initially wound single coil layer is wound.

Referring to FIGS. 1 through 5, a coil component 100 according to the embodiment of the present invention may be an insulating type switching transformer and may include a bobbin 10, a core 40, and a coil 50.

The bobbin 10 may form an entire body of the coil component. The bobbin 10 may be easily manufactured by injection molding, but is not limited thereto. In addition, the bobbin 10 according to the present embodiment may be formed of an insulating resin and be formed of a material having high heat resistance and high voltage resistance. As a material of the bobbin 10, for example, polyphenylenesulfide (PPS), liquid crystal polyester (LCP), polybutyleneterephthalate (PBT), polyethyleneterephthalate (PET), phenolic resin, and the like, may be used.

The bobbin 10 may include a winding part 12 having the coil 50 wound thereon and a terminal connection part 20 formed at one end of the winding part 12.

The winding part 12 may include a body part 13 having a cylindrical shape and a flange part 15 extended from both ends of the body part 13 in an outer diameter direction.

An inner portion of the body part 13 may be provided with a through-hole 11 into which a portion of the core 40 is inserted. In addition, the coil 50 is wound on an outer surface of the body part 13.

The flange part 15 may protrude to be extended from both ends, that is, upper and lower ends, of the body part 13 in the outer diameter direction. The flange part 15 according to the present embodiment may be divided into an upper flange part 15a and a lower flange part 15b according to a position thereof.

In addition, a space between the outer peripheral surface of the body part 13 and the upper and lower flange parts 15a and 15b is formed as a winding space on which the coil 50 is wound. Therefore, the flange parts 15 may serve to protect the coil 50 from the outside and secure insulation properties therebetween, while simultaneously supporting the coil 50 wound on the winding space at both sides thereof.

The terminal connection part 20 may be formed on the lower flange part 15b. More specifically, the terminal connection part 20 according to the present embodiment may be formed at both ends of the lower flange part 15b in order to secure an insulation distance.

Meanwhile, as illustrated, since the terminal connection part 20 according to the present embodiment is partially extended from the lower flange part 15b, it may be difficult to clearly distinguish the terminal connection part 20 from the lower flange part 15b. Therefore, according to the present embodiment, the lower flange part 15b itself may also be perceived as the terminal connection part 20.

The terminal connection part 20 may include a plurality of external connection terminals 34 connected thereto.

In addition, in the bobbin 10 according to the present embodiment, the outer peripheral surface of the body part 13 may be uneven in order to uniformly distribute the coils 50 to be described below. More specifically, the body part 13 may include at least one or more spacing parts 22, and the spacing parts 22 may form uneven portions on the outer surface of the body part 13.

As shown in FIG. 4, the spacing parts 22 may be formed as partitions for dividing spaces on the outer peripheral surface of the body part 13 in a length direction thereof. In this configuration, the coils 50 may be wound on respective spaces partitioned by the spacing parts 22.

In addition, the spacing part 22 according to the present embodiment may be protruded to have a height corresponding to a thickness of the coil 50 wound on the winding part 12, that is, a diameter of the coil 50. More specifically, the spacing part 22 may be protruded to have the height equal to or less than the diameter of the coil 50 initially wound on the winding part 12.

Therefore, as shown in FIG. 4, in the case in which only a single layer of the coils 50 is wound on the winding part 12, the outer surface of the coils and ends of the spacing parts 22 may form a continuous outer peripheral surface S, which is approximately even.

The bobbin 10 according to the present embodiment may include a plurality of spacing parts 22. Therefore, the winding part 12 according to the present embodiment may include a plurality of partitioned spaces.

In addition, the spacing parts 22 according to the present embodiment may be formed to have a partition wall shape, and the spacing parts 22 may be provided with at least one or more skip grooves 22a. The skip groove 22a may be used as a route in which the coil 50 wound in any one space of the spacing part 22 moves to another space adjacent thereto. Therefore, the plurality of skip groove 22a may be provided in various positions as necessary.

The skip groove 22a may be formed by entirely removing a portion of the spacing part 22 to thereby allow the outer surface of the body part 13 to be exposed. In addition, a width of the skip groove 22a may be greater than the thickness (that is, the diameter) of the coil 50.

Meanwhile, since the spacing parts 22 are provided in order to uniformly distribute and wind the coils 50 on the winding part 12, the spacing parts 22 may have various thicknesses and be made of various materials as long as the form thereof may be maintained.

In addition, although the spacing part 22 is formed integrally with the bobbin 10 in the present embodiment byway of example, the present invention is not limited thereto. For example, the spacing part 22 may be formed as a separate member and be then coupled to the bobbin 10.

The core 40 may be partially inserted into the through-hole 11 formed in the bobbin 10 and be electromagnetically coupled to the coils 50 to form a magnetic path.

The core 40 according to the present embodiment may be provided in pair. The pair of cores 40 may be partially inserted into the through-hole 11 of the bobbin 10 to thereby be coupled to each other so as to contact each other. As the cores 40, an ‘EE’ core, an ‘EI’ core, a ‘UU’ core, a ‘UI’ core, or the like may be used.

The core 40 may be formed of Mn—Zn based ferrite having higher permeability, lower loss, higher saturation magnetic flux density, higher stability, and lower production cost, as compared to other materials. However, in the embodiment of the present invention, the shape and material of the core 40 are not particularly limited.

Meanwhile, in order to secure insulation properties between the coil 50 wound on the bobbin 10 and the core 40, an insulating cover (not shown) may be interposed between the bobbin 10 and the core 40.

The insulating cover may be interposed between the bobbin 10 and the entirety of an inner surface of the core 40 facing the bobbin 10 or be only partially interposed therebetween with respect to a facing portion of the coil 50 and the core 40.

The insulating cover may be a cover formed of insulating tape or a resin material. However, the present invention is not limited thereto.

The coil 50 may be wound on the winding part 12 of the bobbin 10 and include primary and secondary coils.

Each of the primary coil and the secondary coil may include a plurality of individual coils that are electrically insulated from each other. Here, the number of the primary and secondary coils may be appropriately changed as necessary.

The primary and the secondary coils according to the present embodiment of the invention may be stacked and wound on the bobbin 10.

As the coil 50 according to the present embodiment, a general insulated coil (for example, a polyurethane wire, or the like), and a coil formed by twisting several strands of wires (for example, a Litz wire, or the like) may be used. In addition, a multi-insulated coil (for example, a triple insulated wire (TIW), or the like) having high insulation properties may be used. That is, types of the coils may be selected as necessary.

The coil component 100 according to the present embodiment includes the spacing parts 22 in order to allow the coils 50 initially wound on the winding part 12, that is, the coils 50 wound thereon while directly contacting the outer peripheral surface of the body part 13 to be uniformly disposed within the winding part 12. A detailed description thereof will be provided below.

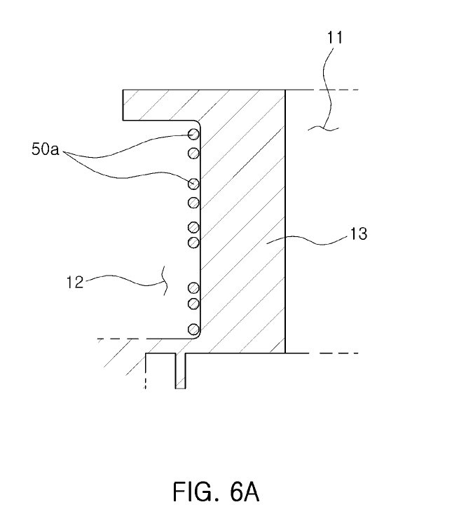

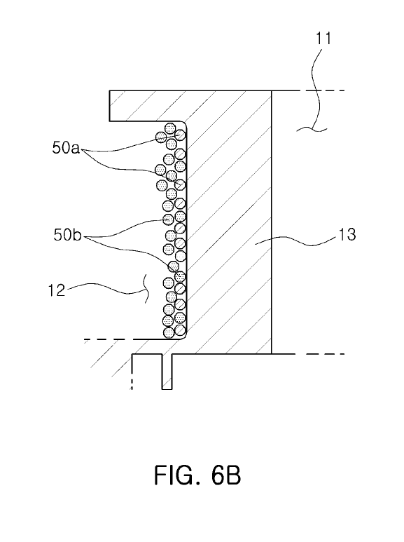

FIGS. 6A and 6B are cross-sectional views schematically showing a coil component according to the related art, FIG. 6A shows a state in which only an initially wound single coil layer is wound, and FIG. 6B shows a state in which two coil layers are wound.

Referring to this, as shown in FIG. 6A, in the case in which the winding number (that is, the number of turns) of the initially wound coils 50a is less than a width of the winding part 12, the coils 50a may be wound in a relatively greater amount on any one side or may be non-uniformly wound. That is, in the case in which the winding number of the coils 50a disposed in a single layer is small, it is difficult to uniformly distribute and wind the coils 50a on winding part 12.

In this case, coils (50b in FIG. 6B) stacked outside of the initially wound coils 50a are also affected by a form in which the initially wound coils 50a are disposed. Therefore, as shown in FIG. 6B, the coils 50b stacked on the initially wound coils 50a may also be non-uniformly wound.

In the case in which the coils 50a and 50b are non-uniformly wound as described above, the leakage inductance of the coil component is increased.

However, as shown in FIG. 5, in the coil component 100 according to the present embodiment, the spacing parts 22 serve to fill the spaces between the initially wounded coils 50 and to fix the movement of the initially wounded coils 50. That is, the initially wound coils 50 may be wound on the winding part 12 while being distributed to have uniform intervals due to the spacing parts 22, and may not be shaken or moved due to the spacing parts 22 even after winding.

In addition, since the spacing parts 22 according to the present embodiment are protruded to have the approximately same height as the diameter of the initially wound coils 50, the outer peripheral surface S formed by the initially wound coils 50 and the spacing parts 22 may form an approximately even surface without uneven portions. Therefore, since the coils 50 stacked outside of the initially wound coils 50 are wound on the outer peripheral surface S, they may be uniformly wounded.

Meanwhile, the present invention is not limited to the above-mentioned configuration, but may be variously modified as necessary.

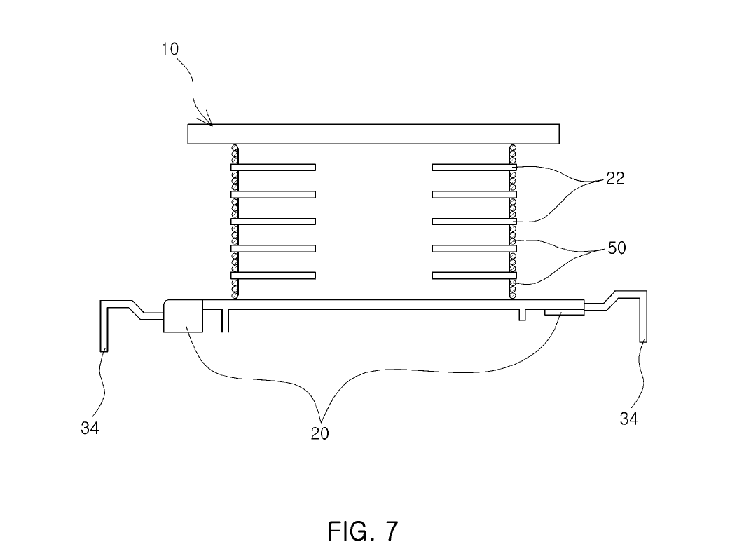

FIGS. 7 through 9 are cross-sectional views schematically showing coil components according to other embodiments of the present invention.

First, referring to FIG. 7, in the coil component according to the present embodiment, the coils 50 are wound between the spacing parts 22 not only one time, but multiple times. Although FIG. 7 shows a case in which the coils 50 are wound three times in a space between the spacing parts 22 disposed adjacently to each other, the present invention is not limited thereto, but may be changed in various forms as necessary.

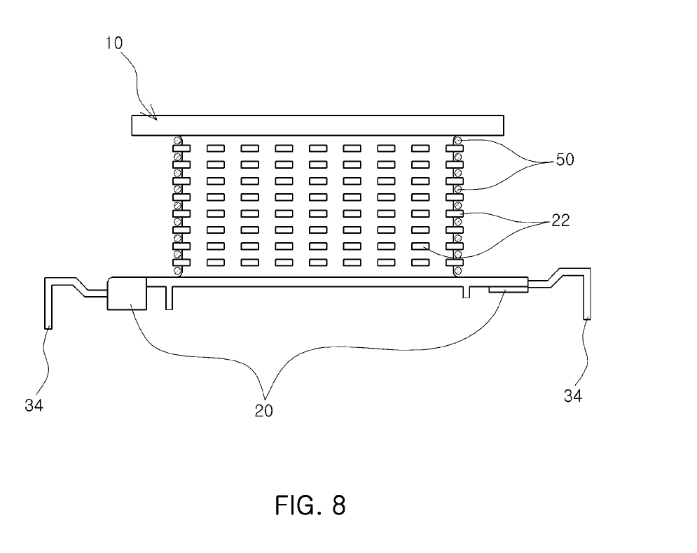

In addition, referring to FIG. 8, in the coil component according to the present embodiment, the spacing parts 22 have the form of protrusions, not having the partition wall shape. In this case, intervals between respective protrusions may be set to have various distances according to the size of the bobbin 10, the thickness of the coil 50, and the like.

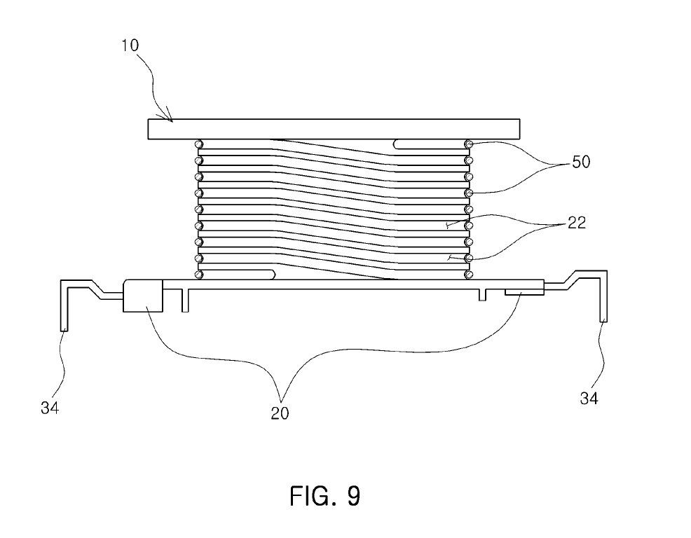

In addition, referring to FIG. 9, in the coil component according to the present embodiment, the spacing parts 22 have the form of grooves, not having the form of protrusions. In this case, the groove is formed to have a width and depth corresponding to the diameter of the coil 50 along a route in which the coil 50 is wound. More specifically, the groove may be formed to have a depth equal to or shallower than the diameter of the coil 50 initially wound on the bobbin 10.

As described above, the spacing parts 22 according to the embodiments of the present invention may be changed to have various forms, as necessary.

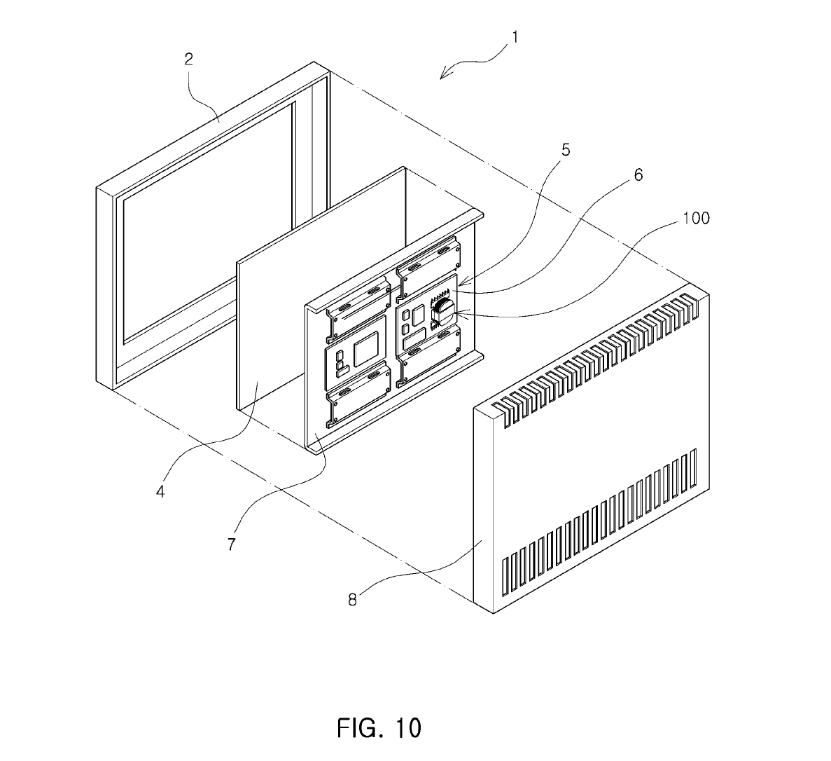

FIG. 10 is an exploded perspective view schematically showing a display device according to an embodiment of the present invention.

Referring to FIG. 10, a display device 1 according to the embodiment of the present invention may include a display panel 4, a power supply 5 having the coil component 100 mounted therein, and covers 2 and 8.

The covers 2 and 8 may include a front cover 2 and a back cover 8 and may be coupled to each other to thereby form a space therebetween.

The display panel 4 may be disposed in the internal space formed between the covers 2 and 8. As the display panel 4, various flat panel display panels such as a liquid crystal display (LCD), a plasma display panel (PDP), an organic light emitting diode (OLED), and the like, may be used.

The switching mode power supply (SMPS) 5 may provide power to the display panel 4. The SMPS 5 may be formed by mounting a plurality of electronic components on a printed circuit board 6. In particular, the SMPS 5 may include at least one or more coil components 100 according to the above-mentioned embodiments mounted therein.

The SMPS 5 may be fixed to a chassis 7 and be fixedly disposed in the internal space formed between the covers 2 and 8, together with the display panel 4.

The coil component and the display device including the same are not limited to the above-described embodiments, and those skilled in the art will appreciate that various modifications, additions and substitutions are made, without departing from the scope and sprit of the invention.

In addition, in the above-described embodiment, the insulating type switching transformer has been described as an example of coil components. However, the present invention is not limited thereto, but may be variously applied to a component using a coil wound thereon such as a transformer for an inverter, a high frequency filter or the like, and an electronic device including the same.

As set forth above, in a coil component according to an embodiment of the present invention, a spacing part serves to fill a space between initially wound coils and to fix the movement of the initially wound coils. Therefore, the initially wound coils may be wound on an winding part while being distributed at an uniform interval due to the spacing part, and may not be shaken or moved due to the spacing part even after winding.

In addition, since the spacing part according to the embodiment of the present invention is protruded to have the approximately same height as the diameter of the initially wound coil, an outer peripheral surface formed by the initially wound coil and the spacing part may form an approximately even surface without uneven portions. Therefore, since the coils stacked outside of the initially wound coil are wound on the above-mentioned outer peripheral surface, they may be uniformly wounded.

As a result, leakage inductance that may be caused due to unbalanced winding of the coils may be significantly reduced.

While the present invention has been shown and described in connection with the embodiments, it will be apparent to those skilled in the art that modifications and variations can be made without departing from the spirit and scope of the invention as defined by the appended claims.

What is claimed is:

1. A coil component, comprising:
a cylindrical body part having a plurality of coils wound and stacked on an outer peripheral surface thereof; and
one or more spacing parts formed on the outer peripheral surface of the body part to uniformly distribute the coils directly wound on the body part.

2. The coil component of claim 1, wherein the spacing parts are protruded from the body part while having a height equal to or less than a diameter of the coil.

3. The coil component of claim 2, wherein the spacing parts are formed to have a partition wall shape and include one or more skip grooves.

4. The coil component of claim 2, wherein the spacing parts are formed as a plurality of protrusions.

5. The coil component of claim 2, wherein a space between two adjacent spacing parts is formed to have a width corresponding to the diameter of the coil.

6. The coil component of claim 2, wherein the coils are stacked and wound on ends of the spacing parts.

7. The coil component of claim 1, wherein the spacing parts are formed as grooves in the body part, the groove having a depth equal to or shallower than a diameter of the coil.

8. The coil component of claim 1, wherein the coils directly wound on the body part form a continuous outer peripheral surface, evenly with the spacing parts.

9. A coil component, comprising:
a cylindrical body part having uneven portions formed on an outer peripheral surface thereof; and
a plurality of coils stacked and wound on the uneven outer peripheral surface of the body part.

10. A display device, comprising:
a power supply having at least one coil component of claim 1 mounted on a substrate; and
a display panel receiving power from the switching mode power supply.
